(19) United States
(12) Patent Application Publication
(10) Pub. No.: US 2018/0100878 A1
(43) Pub. Date: Apr. 12, 2018

(54) SENSING DEVICE FOR AN ELECTRICAL SYSTEM

(71) Applicant: Cooper Technologies Company, Houston, TX (US)

(72) Inventors: Michael Davis Pearce, Plum Branch, SC (US); Travis Spoone, Greenwood, SC (US); Ljubomir A. Kojovic, Racine, WI (US)

(21) Appl. No.: 15/712,289

(22) Filed: Sep. 22, 2017

Related U.S. Application Data
(60) Provisional application No. 62/405,674, filed on Oct. 7, 2016.

(51) Int. Cl. G01R 15/16; H01R 13/73; G01R 15/18

(52) U.S. Cl. CPC G01R 15/16; H01R 2201/20; G01R 15/181; H01R 13/73

(57) ABSTRACT

A sensing device incudes: a housing including an electrical interface and a surface, the surface defining a first connection interface and a second connection interface, the first connection interface configured to connect the housing to a bushing, the second connection interface configured to connect the housing to a separate electrical device, the electrical interface being configured to electrically connect to an electrical conductor of the electrical device; a capacitive voltage sensor including a plurality of capacitors, at least one of the plurality of capacitors being in a first portion of the housing, the at least one capacitor in the first portion of the housing and at least one other capacitor of the plurality of capacitors arranged relative to each other to form a capacitive divider; and a current sensor in a second portion of the housing.

### CROSS-REFERENCE TO RELATED APPLICATION

This application claims the benefit of U.S. Provisional Application No. 62/405,674, filed on Oct. 7, 2016 and titled SENSING DEVICE FOR AN ELECTRICAL SYSTEM, which is incorporated herein by reference in its entirety.

### TECHNICAL FIELD

This disclosure relates to a sensing device for an electrical system. The sensing device includes a current sensor and a capacitive voltage sensor in a housing.

### BACKGROUND

In a medium to high-voltage power distribution network, the voltage of a current-carrying conductor may be measured with a voltage sensor, such as a voltage sensor made out of resistors or a capacitive voltage sensor that includes capacitors arranged as a capacitive divider. The voltage sensor may be integrated with a bushing that connects to the current-carrying conductor.

### SUMMARY

In one general aspect, a sensing device incudes: a housing including an electrical interface and a surface, the surface defining a first connection interface and a second connection interface, the first connection interface configured to connect the housing to a bushing, the second connection interface configured to connect the housing to a separate electrical device, the electrical interface being configured to electrically connect to an electrical conductor of the electrical device; a capacitive voltage sensor including a plurality of capacitors, at least one of the plurality of capacitors being in a first portion of the housing, the at least one capacitor in the first portion of the housing and at least one other capacitor of the plurality of capacitors arranged relative to each other to form a capacitive divider; and a current sensor in a second portion of the housing, the first portion of the housing and the second portion of the housing being in physical contact with each other.

Implementations may include one or more of the following features. The surface of the housing may include an inner surface and an outer surface, the inner surface defining an opening, the opening may be the first connection interface and the opening may be configured for placement on an exterior of the bushing, and a portion of the outer surface may be the second connection interface and is configured to be received in an opening of the separate electrical device. The plurality of capacitors may include a first capacitor and a second capacitor, the first capacitor may be the at least one capacitor of the plurality of capacitors in the first portion of the housing, the second capacitor may be in the second portion of the housing, and the first capacitor and the second capacitor may be arranged relative to each other to form the capacitive divider. The first capacitor may include a first electrode; a second electrode separated from the first electrode, the second electrode configured for galvanic connection to the electrical conductor; and a dielectric material between the first and second electrodes. The first electrode and the second electrode may be in parallel planes and angled relative to a longitudinal axis of the housing.

The opening defined by the inner surface of the housing may be configured to make contact with and surround a portion of the exterior of the bushing.

The current sensor may include a Rogowski coil.

The sensing device also may include an electronic module in the second portion of the housing, the electronic module including an electronic memory and a data interface, the data interface being accessible from an exterior of the housing.

The first portion of the housing and the second portion of the housing may be a single, integral piece.

The first portion of the housing and the second portion of the housing may be formed as separate pieces configured for physical connection to each other, the first portion of the housing being a first separate piece and the second portion of the housing being a second separate piece. The second separate piece may be configured to surround at least part of the first separate piece. The second capacitor, the electronics module, and the current sensor may be encapsulated and spatially fixed relative to each other in the second portion.

The plurality of capacitors the plurality of capacitors may include a first capacitor and a second capacitor, the first capacitor may be in the first portion of the housing, the first capacitor may include: a first electrode, a second electrode separated from the first electrode, and a dielectric material between the first and second electrodes. The second capacitor may be formed between one of the first and second electrodes of the first capacitor and an electrical conductor connected to the bushing.

In one general aspect, a system includes a bushing; an electrical connector including an electrical conductor, the electrical conductor configured for electrical connection to the bushing; and a sensing device including: a housing configured to be connected between the bushing and the electrical connector; an electrical interface configured to electrically connect to the electrical conductor; a capacitive voltage sensor including a plurality of capacitors arranged relative to each other to form a capacitive divider configured to measure a voltage, at least one of the plurality of capacitors being in a first portion of the housing; and a current sensor in a second portion of the housing, where, when the sensing device is connected between the bushing and the electrical connector, the capacitive voltage sensor measures a voltage of the electrical conductor and the current sensor measures a current that flows in the electrical conductor.

Implementations may include one or more of the following features. The current sensor my include a Rogowski coil. The housing of the sensing device may be a single, integral piece.

The first portion of the housing and the second portion of the housing may be formed as separate pieces configured to be physically connected to each other, the first portion of the housing may be a first separate piece and the second portion of the housing may be a second separate piece, and, when the sensing device is connected between the bushing and the electrical connector, the first separate piece may make physical contact with the bushing and the electrical connector and the second separate piece surrounds the first separate piece.

In another general aspect, a housing of a sensing device is connected to a bushing and an electrical connector, the housing of the sensing device being between the bushing and the electrical connector, and an electrical conductor of the electrical connector being electrically coupled to the bushing; an indication of an amount of current flowing in the electrical conductor is received from a current sensor in the housing; and an indication of an amount of voltage at the electrical conductor is received from a capacitive voltage sensor in the housing.

Implementations of any of the techniques described herein may include an apparatus, a device, a system, and/or a method. The details of one or more implementations are set forth in the accompanying drawings and the description below. Other features will be apparent from the description and drawings, and from the claims.

### DRAWING DESCRIPTION

FIGS. 1A and 1B are block diagrams of an electrical system that includes an example of a sensing device.

FIG. 2A is a side cross-sectional view of an example of a sensing device.

FIG. 2B is a schematic circuit diagram of a capacitive voltage sensor that may be used in the sensing device of FIG. 2A.

FIG. 2C is a perspective view of a capacitor that may be used in the sensing device of FIG. 2A.

FIG. 2D is a front cross-sectional view of the sensing device of FIG. 2A taken along the line 2D-2D of FIG. 2A.

FIG. 2E is a front cross-sectional view of an example of a Rogowski coil that may be used in the sensing device of FIG. 2A.

FIG. 3A is a cross-sectional view of another example of a sensing device.

FIG. 3B is a front-cross sectional view of a second portion of the sensing device of FIG. 3A.

FIG. 4 is a side cross-sectional view of another example of an electrical system.

FIG. 5A is a cross-sectional view of another example of a sensing device.

FIG. 5B is a perspective view of a capacitor that may be used in the sensing device of FIG. 5A.

FIG. 6 is a side cross-sectional view of a bushing connected to another example of a sensing device.

### DETAILED DESCRIPTION

A sensing device that includes a current sensor and a capacitive voltage sensor in an single, unitary insulating housing, or two separately formed and physically connectable insulating housings, is disclosed. The sensing device may be used to retrofit an existing system that lacks a current and/or voltage sensor.

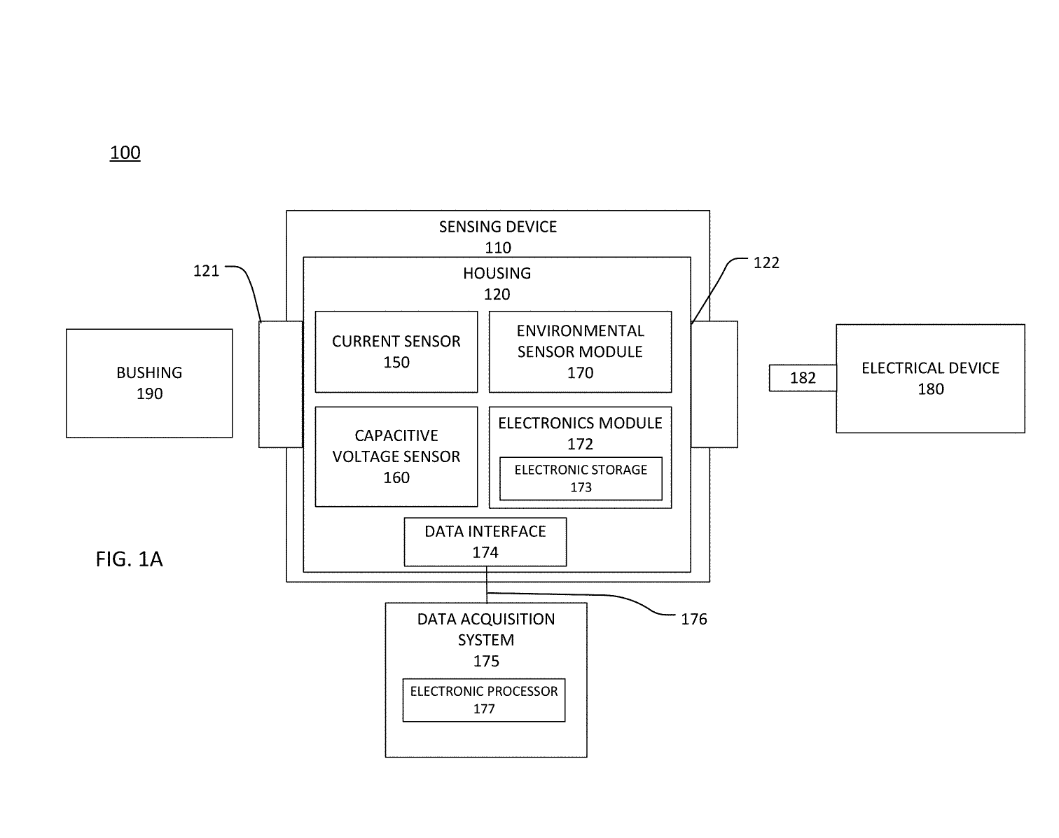

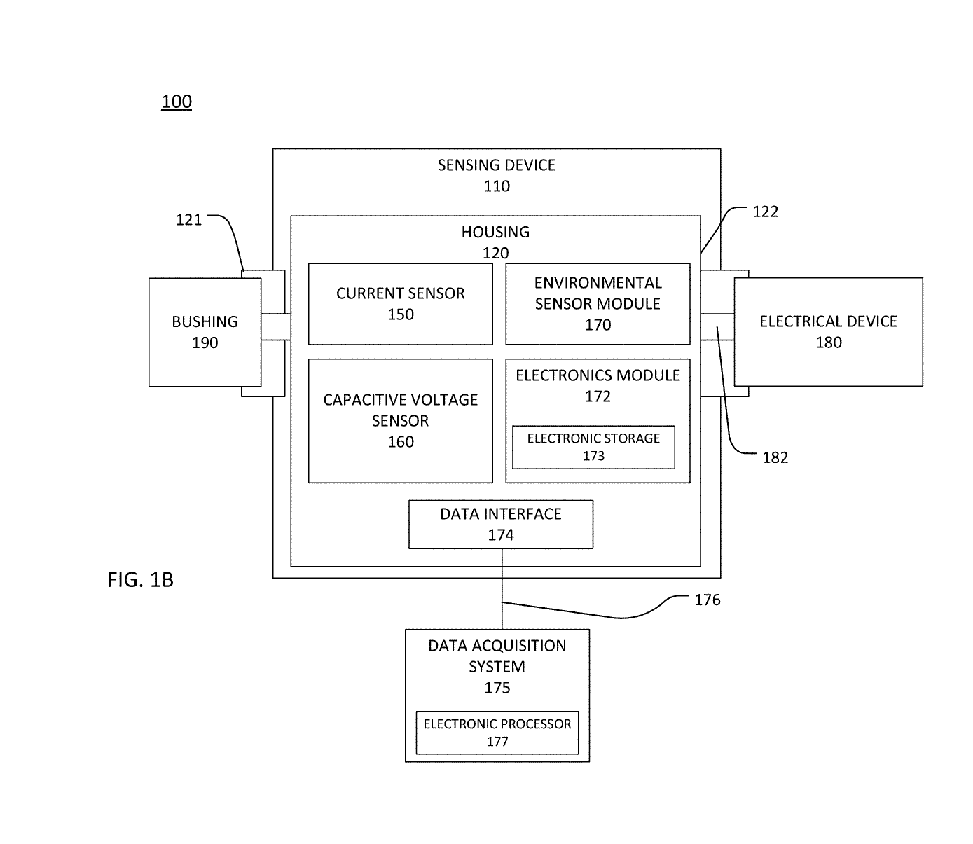

FIGS. 1A and 1B are block diagrams of an example of an electrical system 100. The electrical system 100 may be used in a medium-voltage or high-voltage electrical power distribution network that nominally operates at voltages of, for example, 1 kilovolt (kV) to 50 kV, 12 to 36 kV, or greater than 10 kV, and that may experience voltage surges of up to, for example, 95 kV or 100 kV. The electrical power distribution network may operate at a fundamental frequency of, for example, 60 Hertz (Hz). The electrical power distribution network may be, for example, a municipal power grid that serves residential and commercial customers.

The electrical system 100 includes a sensing device 110. The sensing device 110 includes a current sensor 150 and a capacitive voltage sensor 160, both of which are enclosed in a housing 120. The housing 120 of the sensing device 110 defines a first connection interface 121 and a second connection interface 122. The first connection interface 121 connects the housing 120 to a bushing 190, and the second connection interface 122 connects the housing 120 to an electrical device 180.

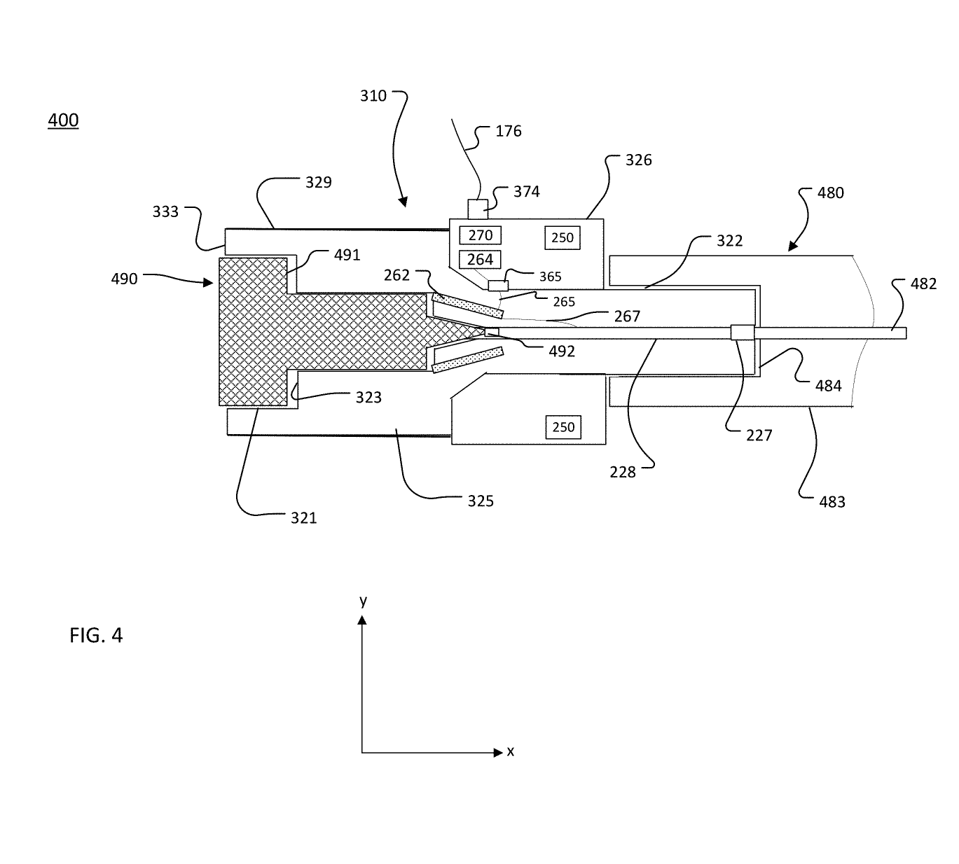

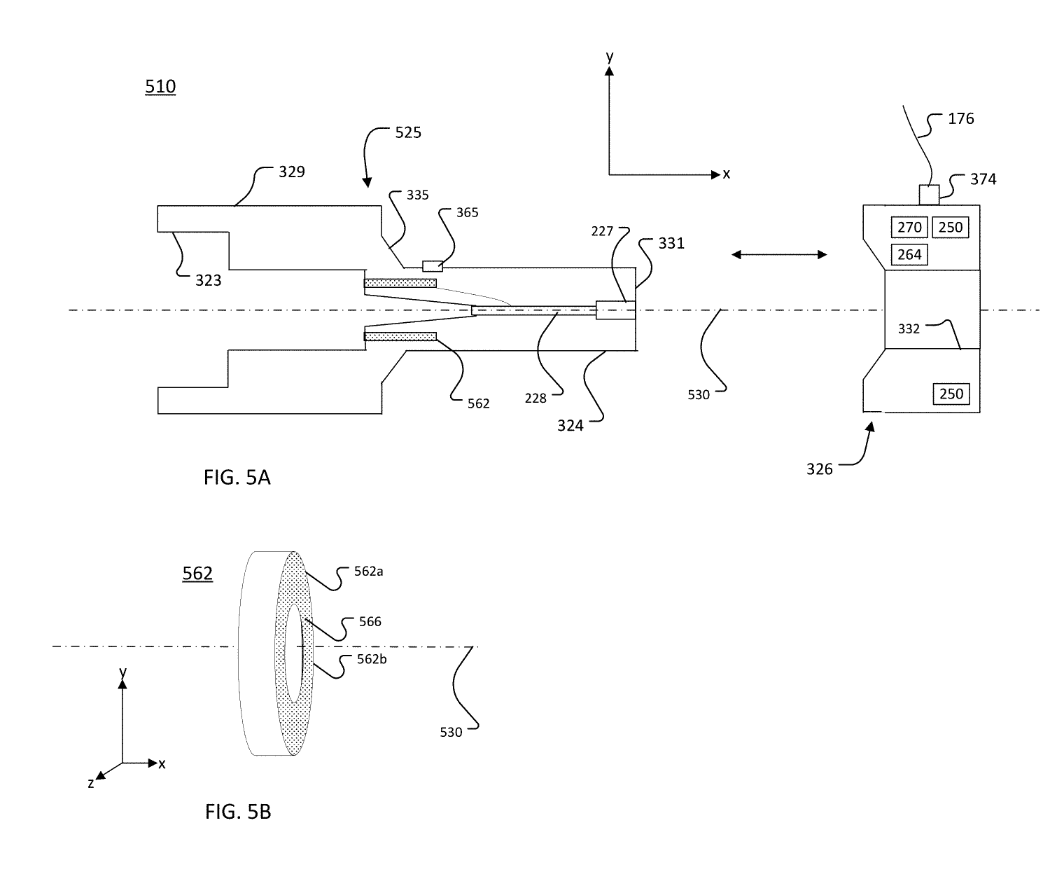

The bushing 190 is an insulated device that allows current to be conducted from one side of a barrier to another side of the barrier safely. The electrical device 180 may be, for example, a load break or dead break elbow connector or a T-body connector. The electrical device 180 includes an electrical conductor 182, which is configured to connect other electrical equipment in the power distribution network to the bushing 190. For example, the electrical conductor 182 of the device 180 may connect to a switchgear, a transformer, a sectionalizer, or underground electrical distribution equipment. The bushing 190 includes a conductive passage or element (such as the electrical connection 492 of FIG. 4). The conductive passage or element of the bushing 190 connects to the conductor 182 such that electrical current flowing in the conductor 182 may be conducted from one side of the bushing barrier to another side.

FIG. 1A shows the electrical system 100 in a disconnected state in which the sensing device 110 is not connected to the electrical device 180 or the bushing 190. FIG. 1B shows the sensing device 110 in a connected state in which the sensing device 110 is connected to the bushing 190 at the first connection interface 121 and to the electrical device 180 at the second connection interface 122. As shown in FIG. 1B, the sensing device 110 is connected between the bushing 190 and the electrical device 180. When the sensing device 110 is in the connected state, current in the electrical conductor 182 flows through the sensing device 110 and into the bushing 190. The current sensor 150 measures a current that flows in the electrical conductor 182, and the capacitive voltage sensor 160 measures a voltage at the electrical conductor 182.

Because the sensing device 110 is separate from the bushing 190 and the electrical device 180, the sensing device 110 may be used to retrofit an existing or legacy system or device in which the bushing and/or the electrical device do not include a current and voltage sensor. Additionally, because the sensing device 110 connects between the bushing 190 and the electrical device 180, the sensing device 110 may be used while the electrical device 180 and the bushing 190 are in operation and while current flows in the conductor 182 to the bushing 190. Moreover, no structural changes are needed to the bushing 190 or the electrical device 180 for the sensing device 110 to connect between the bushing 190 and the electrical device 180.

The sensing device 110 also may include an environmental sensor module 170 and an electronics module 172. The sensor module 170 includes one or more sensors that measure environmental conditions, such as temperature, vibration, and/or strain in or around the sensing device 110. The electronics module 172 includes an electronic storage 173. The electronic storage 173 may be volatile memory, such as RAM, or non-volatile memory, such as an electrically erasable programmable read-only memory (EEPROM). In some implementations, the electronic storage 173 may include both non-volatile and volatile portions or components. Examples of electronic storage may include solid state storage, magnetic storage, and optical storage. Solid state storage may be implemented in, for example, resistor-transistor logic (RTL), complementary metal-oxide semiconductor (CMOS), or carbon nanotubes, and may be embodied in non-volatile or volatile random-access memory.

The current sensor 150, the capacitive voltage sensor 160, and/or any of the sensors in the environmental sensor module 170 may include an instance of the electronic storage 173 in the form of an EEPROM that is embedded in the sensor. For example, the environmental sensing module 170 may include a temperature sensor that has an embedded EEPROM. In some implementations, each of the current sensor 150, the capacitive voltage sensor 160, and all of the sensors in the environmental sensor module 170 have an associated or embedded EEPROM, and the electronic storage 173 depicted in FIGS. 1A and 1B represents all of these associated or embedded EEPROMS.

A transducer electronic datasheet (TEDS) for each sensor may be stored on an EEPROM associated with or embedded in that sensor. Such sensors are TEDS sensors based on, for example, the IEEE 1451.4 standard. A TEDS sensor stores information about the sensor on an associated or embedded EEPROM. The information stored on the EEPROM may be information that informs a user on how to interpret measurement data from the sensor. The information about the sensor may include, for example, the manufacturer, model number, serial number, measurement range, calibration information, and other information that is specific to the sensor.

The TEDS sensor includes a mixed-mode data interface that provides analog and digital signals to a data acquisition system 175 via a link 176. The information on the EEPROM is provided to the data acquisition system 175 as a digital signal. Measurements obtained by the sensor are provided to the data acquisition system 175 as an analog signal.

In FIGS. 1A and 1B, a data interface 174 represents the mixed-mode data interface of one or more TEDS sensors. The data interface 174 may be any type of interface capable of providing digital and analog signals. For example, the data interface 174 may be a serial connection, such as a universal serial bus (USB) connection. The link 176 may be any type of wired or wireless link capable of connecting to the data interface 174. In some implementations, the data interface 174 is connected to the housing 120 in a manner that allows the sensing device 110 to be submerged in a fluid (such as water). In these implementations, the data interface 174 is within a connector that is sealed to the housing 120 with a fluid-tight seal, and the link 176 is an insulated wired connection (such as a cable) that is submersible.

The data acquisition system 175 includes one or more electronic processors 177. The electronic processors 177 may be may be one or more processors suitable for the execution of a computer program such as a general or special purpose microprocessor, and any one or more processors of any kind of digital computer. Generally, a processor receives instructions and data from a read-only memory or a random access memory or both. The electronic processors 177 may be any type of electronic processor, may be more than one electronic processor, and may include a general purpose central processing unit (CPU), a graphics processing unit (GPU), a microcontroller, a field-programmable gate array (FPGA), and/or an application-specific integrated circuit (ASIC). In some implementations, the electronics module 172 includes one or more electronic processors 177 in addition to the electronic storage 173. Additionally, the data acquisition system 175 may include an electronic storage.

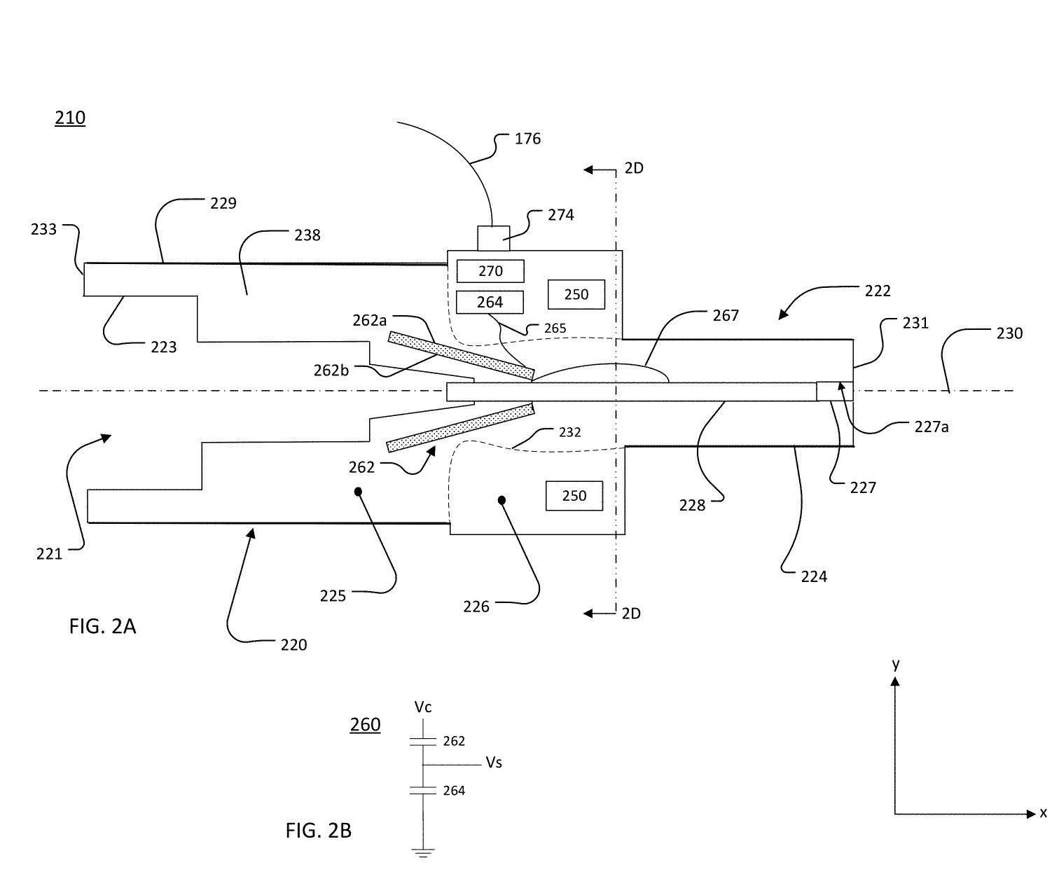

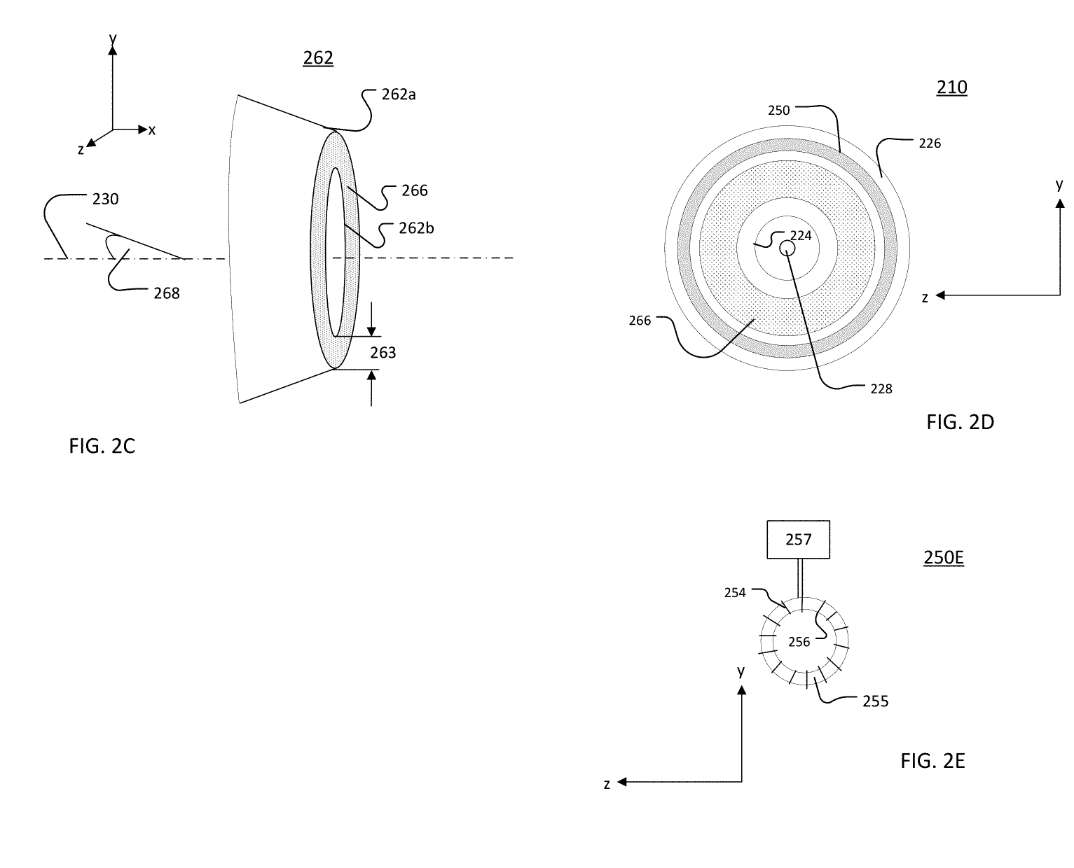

FIG. 2A is a side cross-sectional block diagram of a sensing device 210. The sensing device 210 is an example of an implementation of the sensing device 110, and the sensing device 210 may be used in the electrical system 100. The sensing device 210 includes a current sensor 250 and a capacitive voltage sensor 260. The capacitive voltage sensor 260 is a capacitive divider formed from capacitors 262 and 264. FIG. 2B is a schematic circuit diagram of the capacitive voltage sensor 260.

The sensing device 210 also includes a housing 220, which is radially symmetric about a longitudinal axis 230. The housing 220 includes an electrical interface 227 at an end 231 and a passage 228 that extends from the electrical interface 227 along the longitudinal axis 230. The passage 228 may be an electrically conductive passage that electrically connects to a conductor received at the electrical interface 227. In some implementations, the passage 228 is an insulated bore or space that receives a conductor that connects to the sensing device 210 at the electrical interface 227.

The electrical interface 227 includes an inner surface 227a. The inner surface 227a is an electrically conductive material. For example, the electrical interface 227 may be a metallic material. The conductor contacts the inner surface 227a. The inner surface 227a may have surface features that enhance the physical connection between the conductor and the inner surface 227a. For example, the inner surface 227a may include threads that match corresponding threads on the conductor. The current sensor 250 measures current that flows in the conductor, and the capacitive voltage sensor 260 measures the voltage at the conductor.

The housing 220 includes an inner surface 223 and an outer surface 224. A portion of the inner surface 223 defines a first connection interface 221, which is at an end 233. A portion of the outer surface 224 defines a second connection interface 222, which is at the end 231. The first and second connection interfaces 221, 222 are mechanical interfaces that physically connect the housing 220 to another object. For example, the first connection interface 221 may be an opening formed by the inner surface 223, and the second connection interface 222 may be a portion of the outer surface 224 shaped to be received in a corresponding opening of a separate device. In this way, the sensing device 210 may be connected between two separate objects (such as the electrical device 180 and the bushing 190 of FIGS. 1A and 1B).

The housing 220 is a single, unitary housing filled with or formed from an insulating material 238. The housing 220 has a first portion 225 and a second portion 226. The first portion 225 and the second portion 226 are adjoining spatial regions within the housing 220. A dashed line labeled 232 shows an example spatial arrangement of the first portion 225 and the second portion 226 within the housing 220.

The insulating material 238 may be molded into a single piece to form the housing 220, with the single, molded piece including the first portion 225 and the second portion 226. In some implementations, the first portion 225 and the second portion 226 are individual insulating housings that are separately molded and then permanently joined together to form the housing 220. Additionally, the insulating material 238 may be the same throughout the housing 220, or the insulating material 238 may be a collection of materials such that the insulating material is not uniform throughout the housing 220. The housing 220 may be made from, for example, silicone and/or ethylene propylene diene monomer rubber (EPDM).

In the example of FIG. 2A, the capacitor 262 is in the first portion 225. Referring also to FIG. 2C, which is a side perspective view of the capacitor 262, the capacitor 262 includes electrodes 262a and 262b, which are separated by a distance 263. The electrodes 262a, 262b each have a cone-like shape. The electrodes 262a and 262b are concentric with each other and with the longitudinal axis 230, and the electrode 262b is between the longitudinal axis 230 and the electrode 262a. A dielectric material 266 is between the electrodes 262a and 262b. The dielectric material 266 may be any insulating material such as, for example, ceramic.

The amount of capacitance provided by the capacitor 262 is proportional to the surface area of the electrodes 262a and 262b divided by the distance 263. The capacitor 262 may have a capacitance of, for example, tens of picofarads (pF). The electrodes 262a and 262b extend at an angle 268 relative to the longitudinal axis 230. The angle 268 may correspond to an angle of a housing of a bushing (for example, the bushing 190) to which the sensing device 210 is connected. The angle 268 may be several degrees, for example, the angle 268 may be 1-10 degrees (°).

Compared to an implementation in which the electrodes 262a and 262b are parallel with the longitudinal axis 230, positioning the electrodes 262a, 262b at the angle 268 allows the surface area of the electrodes 262a and 262b to be increased without increasing the volume of space required for the capacitor 262. Thus, positioning the electrodes 262a, 262b at the angle 268 may result in a more compact sensing device 210.

Referring again to FIG. 2A, the electrode 262b is connected to the passage 228 via a galvanic connection 267. When an electrical connector is connected to the sensing device 210 at the electrical interface 227, the electrode 262b is electrically connected to the conductor via the connection 267. The galvanic connection 267 may be any direct electrical connection. For example, the connection 267 may an electrically conductive wire connected to the electrode 262b and the passage 228. Although the connection 267 is shown as a wire-like connection in FIG. 2A, the connection 267 may be a connection other than a wire. For example, in some implementations, the galvanic connection 267 is a semiconductive material that contacts the electrode 262b and the passage 228. The connection 267 may be formed by, for example, coating a portion of the insulating material 238 between the electrode 262b and the passage 228 with the semiconductive material. In some implementations, the semiconductive material is positioned to contact the electrode 262b and the passage 228 and then encapsulated into the insulating material 238. A semiconductive material is a material that has a greater resistance than a material that is considered highly conductive (such as, for example, copper) and a lower resistance than a material that is considered an insulator (such as, for example, ceramic). The semiconductive material may be any semiconductive material that has a resistance of, for example, 5-10 ohms per centimeter or 8 ohms per centimeter.

The sensing device 210 also includes the capacitor 264. The capacitor 264 may be an off-the-shelf component. The capacitor 264 has a larger capacitance than the capacitor 262. For example, the capacitor 264 may have a capacitance of hundreds of nanofarads (nf). The capacitor 264 is connected between a ground potential and the electrode 262a of the capacitor 262. The ground potential may be a portion (labeled as 229 in FIG. 2A) of the outer surface 224 of the housing 220. The capacitor 264 is connected to the electrode 262a through a galvanic connection 265. The galvanic connection 265 may be any connection that is able to electrically connect the capacitor 264 and the capacitor 262. For example, the connection 265 may be an electrically conductive wire or a metallic screw.

Connecting the capacitor 264 and the capacitor 262 in this configuration forms a capacitive divider, which is the capacitive voltage sensor 260. The voltage across the capacitor 264 (Vs) may be measured and used to determine the voltage (Vc) between a conductor in the passage 228 and ground based on Equation (1):

$$Vs = Vc ( \frac{{c}_{262}}{{c}_{262} + {c}_{264}} ) , \qquad Equation ( 1 )$$

where C₂₆₂ is the capacitance of the capacitor 262 and C₂₆₄ is the capacitance of the capacitor 264.

The second portion 226 also includes the current sensor 250. The current sensor 250 is concentric with the passage 228 and surrounds the passage 228. FIG. 2D is a front cross-sectional view of the sensing device 210 taken along the line 2D-2D of FIG. 2A. FIG. 2E shows an example of a Rogowski coil 250E, which may be used as the current sensor 250. The Rogowski coil 250E includes a wire 254 wound on a non-magnetic annular core 255. The wire 254 may be, for example, an electrically conductive wire or copper imprinted onto printed circuit boards interconnected with vias. The wire 254 is evenly wound about the core 255 beginning at a starting point 256 and the wire 254 is wound about the core 255 until the wire 254 reaches the starting point 256 again. The two ends of the wire 254 may be connected to signal conditioning module 257. When the Rogowski coil 250E is used as the current sensor 250 and placed in the second portion 226, the core 255 encircles the passage 228. An alternating current (AC) flowing in a conductor received in the passage 228 or a current flowing in the passage 228 induces an instantaneous voltage in the wire 254 that is proportional to the rate of change of the current flowing in the conductor. The voltage in the wire 254 may be provided to the signal conditioning module 257. The signal conditioning module 257 may integrate (add) instantaneous voltages to determine the amount of current flowing in the conductor and/or the signal conditioning module 257 may use the time derivative of the current flowing in the conductor that Rogowski coils inherently produce to monitor the current flowing in the conductor.

The sensing device 210 also includes a sensor module 270. The sensor module 270 may include other sensors for monitoring the status of a bushing (such as the bushing 190, an electrical device (such as the electrical device 180), and/or a conductor (such as the conductor 182). For example, the sensor module 270 may include one or more of a temperature sensor, a vibration sensor, and a strain sensor. The one or more sensors in the sensor module 270 may be TEDS sensors that communicate data through a data interface 274, and each sensor may include an EEPROM.

Additionally, the capacitor 264 may be a TEDS sensor with an associated EEPROM. In these implementations, the capacitive voltage sensor 260 is a TEDS sensor, and information about the capacitors 262 and 264 may be provided via the link 176 to the data acquisition system 175 (FIGS. 1A and 1B) by a digital signal, and the measured voltage may be provided to the data acquisition system 175 by an analog signal.

The current sensor 250 also may be configured as a TEDS sensor. In these implementations, the current sensor 250 has an embedded EEPROM. Information about the current sensor 250 is provided by a digital signal, and voltage data is provided by an analog signal. In these implementations, the signal conditioning module 257 (FIG. 2E) may be part of the data acquisition system 175, or the signal conditioning module 257 may be integrated with the current sensor 250 such that the voltage determined at the module 257 is provided via an analog signal to the data acquisition system 175.

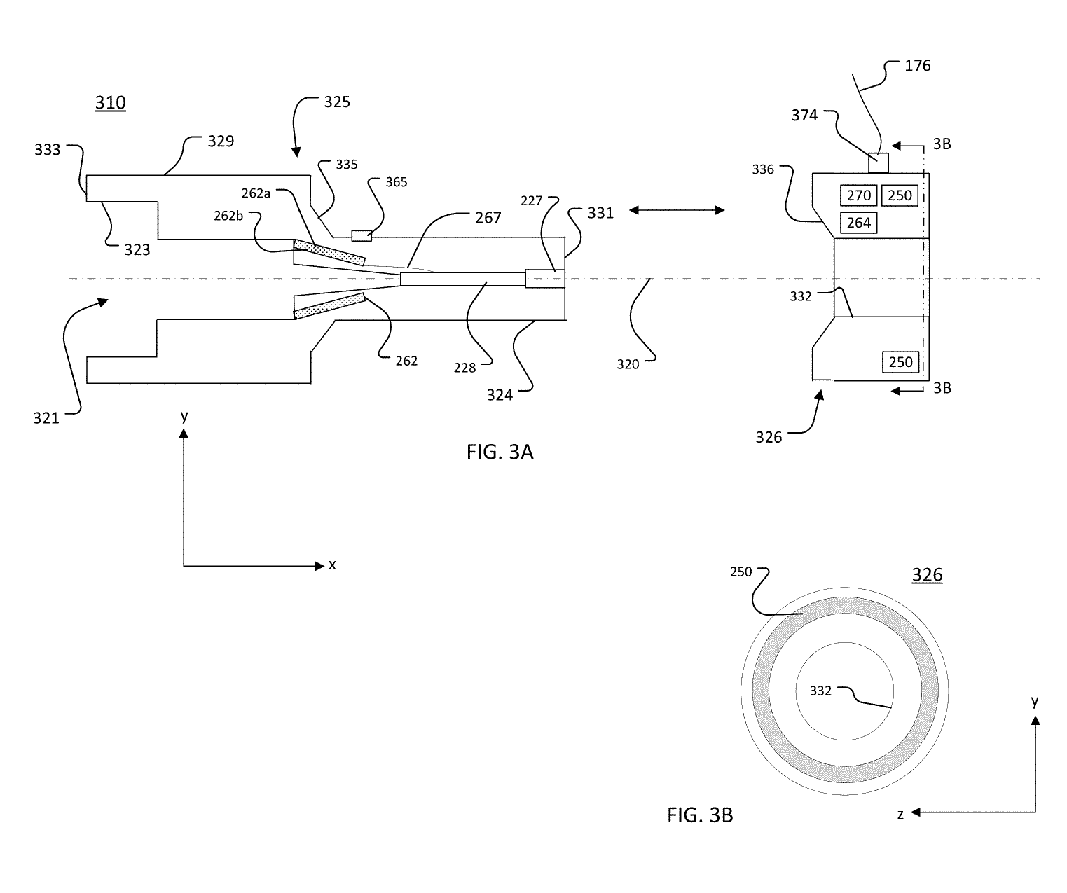

FIG. 3A shows a side cross-sectional view of a sensing device 310, which is another example of an implementation of the sensing device 110. The sensing device 310 includes a first portion 325 and a second portion 326. The sensing device 310 is similar to the sensing device 210 discussed above, except, in the sensing device 310, the first portion 325 and the second portion 326 may be repeatedly connected to and disconnected from each other.

When connected, the first portion 325 and the second portion 326 form the housing of the sensing device 310. The first portion 325 and the second portion 326 extend along a longitudinal axis 320 (which is in the x direction). The first portion 325 and the second portion 326 are radially symmetric about the longitudinal axis 320. The first portion 325 and the second portion 326 are made from an insulating material or a combination of insulating materials.

The first portion 325 includes a first connection interface 321, which is defined by an inner surface 323. The first connection interface 321 is at an end 333 of the first portion 325, and the first connection interface 321 is configured to physically connect to a separate element or device, such as the bushing 190 of FIG. 1A. The first portion 325 also includes a second connection interface 322, which is defined by a portion of an outer surface 324. The second connection interface 322 is configured to physically connect to a separate device or element, such as the electrical device 180 of FIG. 1A. The second connection interface 322 is at an end 331 of the first portion 325. In the example of FIG. 3A, the ends 331 and 333 are opposite ends of the first portion 325 along the x direction. The first portion 325 also includes the electrical interface 227, which is configured to electrically connect to a conductor of a separate device. For example, the electrical interface may connect to the conductor 182 of FIG. 1.

The capacitor 262 is included in the first portion 325. The electrode 262b of the capacitor 262 is connected to the passage 228 via the galvanic connection 267. The first portion 325 also includes an insert 365, which is formed in the outer surface 324. The insert 365 allows for the connection 265 (FIG. 2A) to electrically connect the capacitor 262 to the capacitor 264 when the first portion 325 is connected to the second portion 326. The insert 365 may be, for example, a threaded insert or a bore. The insert 365 allows the connection 265 to be placed into the first portion 325 to reach the electrode 262a of the capacitor 262. In some implementations, part of the connection 265 is in the second portion 326, and part of the connection 265 is in the first portion 325. In these implementations, the insert 365 is electrically conductive and connects the part of the connection 265 in the first portion 325 to the part of the connection in the second portion 326. Additionally, a portion of the outer surface 324 forms a ground plane 329.

The second portion 326 includes the current sensor 250, the second capacitor 264, and the environmental sensor module 270. Although the second portion 326 and the first portion 325 are separable from each other, the components of each of the portions 325 and 326 may remain in a fixed spatial relationship with each other. For example, the current sensor 250, the second capacitor 264, and the sensor module 270 may be encapsulated in the second portion 326 such that these components remain in a fixed spatial relationship with each other within the second portion 326. When the first portion 325 and the second portion 326 are connected, the connection 265, which includes the insert 365, connects the capacitor 264 to the electrode 262a of the capacitor 262. The capacitor 264 and the capacitor 262 form the capacitive voltage sensor 260. The second portion 326 also includes a data interface/connector 374, which is similar to the interfaces 274 (FIG. 2A) and 174 (FIGS. 1A and 1B).

Referring also to FIG. 3B, a bore 332 passes through the center of the second portion 326 in the x direction. FIG. 3B is a front cross-sectional view of the second portion taken along the line 3B-3B of FIG. 3A. The bore 332 allows the second portion 326 to connect to the first portion 325. To connect the second portion 326 and the first portion 325, the end 331 of the first portion 325 is received in the bore 332. The second portion 326 and the first portion 325 are fully connected when a wall 336 of the second portion 326 makes physical contact with a wall 335 on the first portion 325. The wall 335 is part of the outer surface 324 of the first portion 325, and the wall 336 is at an exterior of the second portion 326. The first portion 325 and the second portion 326 remain connected to each other by, for example, a press fit or a friction fit between the outer surface 324 and a surface of the bore 332, or by another physical connection between the first portion 325 and the second portion 326.

FIG. 4 is a cross-sectional side view of an electrical system 400. The electrical system 400 is an example of an implementation of the electrical system 100. The electrical system 400 includes the sensing device 310, which is positioned between a bushing 490 and an electrical device 480 (only a portion of which is shown). The electrical device 480 may be, for example, an elbow or a t-body connector. The electrical device 480 includes an electrical conductor 482, which is used to connect the electrical device 480 between the bushing 490 and other electrical equipment in a power distribution network.

The bushing 490 includes an insulating housing with an exterior surface 491 (shown with cross-hatching in FIG. 4). The exterior surface 491 is shaped to correspond with a shape of the first connection interface 321 of the sensing device 310. The second connection interface 322 of the sensing device 310 is shaped to be received in an opening 484 formed by a housing 483 of the electrical device 480. When the electrical device 480 is connected to the sensing device 310 at the second connection interface 322, the conductor 482 of the electrical device 480 contacts the electrical interface 227 and is inserted into the passage 228. The bushing 490 also includes an electrical connection 492.

When the bushing 490 is fully connected to the sensing device 310, the exterior surface 491 of the housing of the bushing 490 makes physical contact with the inner surface 323 of the first portion 325. The physical contact between the inner surface 323 of the first portion 325 and the exterior surface 491 of the bushing 490 is such that there is no air between the inner surface 323 and the exterior surface 491. The bushing 490 and the sensing device 310 may remain connected to each other due to, for example, a friction fit or a press fit, or other physical contact between the exterior 491 of the bushing 490 and the inner surface 323 of the sensing device 310. Additionally or alternatively, the bushing 490 and the sensing device may be connected to each other with additional fasteners, such as, for example, bolts. Moreover, when the bushing 490 is fully connected to the sensing device 310, the electrical connection 492 connects to the conductor 482, which is received in the passage 228. The electrical connection 492 may be threaded, and the conductor 482 may have corresponding threads. In these implementations, the electrical connection 492 and the conductor 482 may be connected at the threads.

When the electrical device 480 is connected to other equipment in the electrical system 400, current may flow through the conductor 482 and into the bushing 490. The voltage sensor 260 and the current sensor 250 monitor the amount of voltage and current, respectively, in the conductor 482. The amount of voltage and current measured may be read out of the device 310 at the interface 374 and transmitted to the data acquisition system 175 by the link 176 (FIGS. 1A and 1B).

Referring to FIG. 5A, a side cross-sectional view of a sensing device 510 is shown. The sensing device 510 includes housing that has a first portion 525 and the second portion 326 (discussed above with respect to FIG. 3A). The portions 525 and 326 may be repeatedly physically separated and connected to each other. FIG. 5A shows the portions 525 and 326 separated from each other. The portion 525 of the sensing device 510 is similar to the first portion 325 of the sensing device 310 (FIG. 3A), except that the first portion 525 of the sensing device 510 includes a cylindrically shaped capacitor 562.

FIG. 5B shows a perspective view of the capacitor 562. The capacitor 562 includes electrodes 562a, 562b. The electrodes 562a and 562a are concentric with each other and with the longitudinal axis 530, with the electrode 562b being between the longitudinal axis 530 and the electrode 562a. A dielectric material 566 is between the electrodes 562a, 562b.

The capacitor 562 is shown in the sensing device 510 as an example, and the capacitor 562 may be used in other sensing devices. For example, the capacitor 562 may be used instead of the capacitor 262 in the sensing device 210 (FIG. 2A).

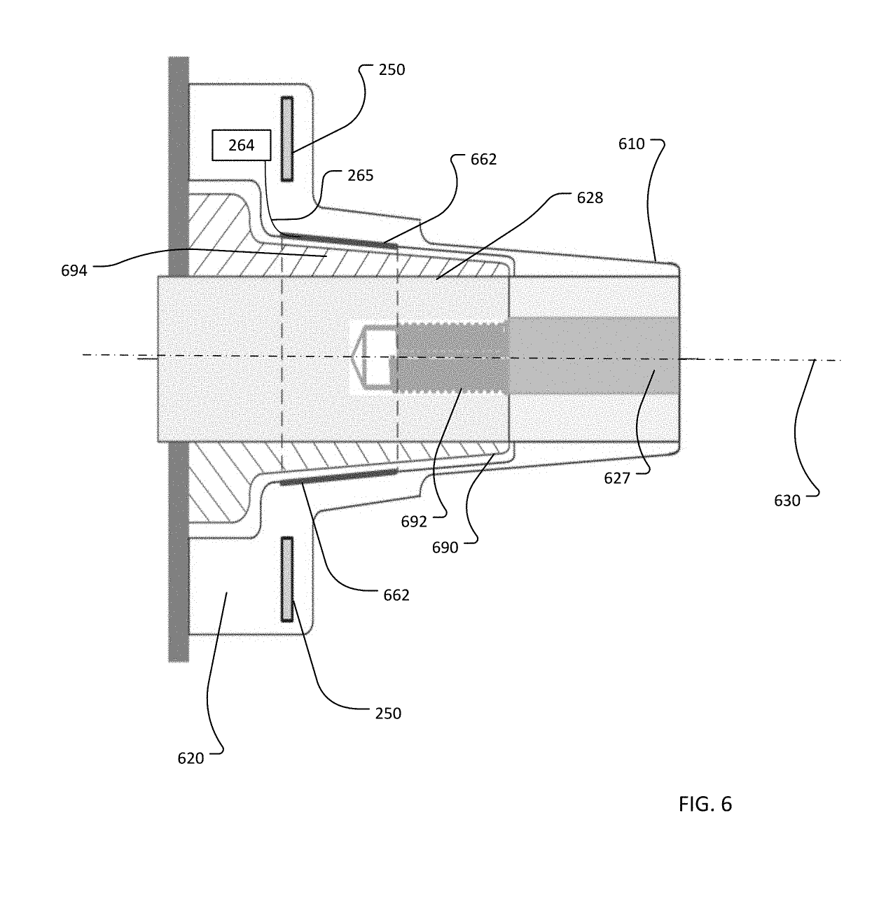

Referring to FIG. 6, a side cross-sectional view of a sensing device 610 connected to a bushing 690 is shown. Although the sensing device 610 is shown as being connected to the bushing 690, the sensing device 610 is not permanently attached to the bushing 690 and the sensing device 610 is not part of the bushing 690.

The sensing device 610 is an example of an implementation of the sensing device 110 of FIGS. 1A and 1B. The sensing device 610 and the bushing 690 are concentric with a longitudinal axis 630. The sensing device 610 includes a housing 620, which encloses the current sensor 250, the second capacitor 264, and an electrode 662. The bushing 690 and the housing 620 of the sensing device 610 are radially symmetric about the axis 630. The current sensor 250 and the electrode 662 are also radially symmetric about the axis 630. The housing 620 defines an electrical interface 627 and passage 628, which extends along the axis 630. The interface 627 is configured to receive a conductor. The bushing 690 includes an electrical interface 692 that electrically connects to the conductor received in the passage 628. The bushing 690 is an insulating body made from an insulating material 694.

The electrode 662 is concentric with the passage 628. The electrode 662 may have an annular shape. For example, the electrode 662 may be a cylinder or a truncated cone that surrounds a region concentric with the passage 628. A truncated cone is the result of cutting a cone by a plane parallel to the base and removing the part containing the apex. When the sensing device 610 and the bushing 690 are attached (as shown in FIG. 6), at least some of the insulating material 694 of the bushing 690 is within the space between the passage 628 and the electrode 662. Thus, the electrode 662 and the conductor (which is in the passage 628) form a capacitor, with the conductor acting as the second electrode of the capacitor and the electrode 662 acting as the first electrode of the capacitor.

The sensing device 610 also includes the second capacitor 264, which is connected to the electrode 662 via the connection 265 such that the second capacitor 264 and the first capacitor (which is the electrode 662 and the conductor in this example) form a capacitive divider. The capacitor 264 may be embedded in the housing 620. The second capacitor 264 has a capacitance that is larger than the capacitance of the capacitor formed by the conductor and the electrode 662. Because the second capacitor 264 and the capacitor formed by the electrode 662 and the conductor are arranged as a capacitive divider, the voltage at the conductor may be determined by measuring the voltage across the second capacitor 264 based on Equation 1. The current flowing in the conductor is measured by the current sensor 250.

The sensing device 610 also may include an environmental sensor, such as the environmental sensor module 170 or 270, and a connector, such as the connector 174.

Other features are within the scope of the claims. For example, although FIGS. 1A, 1B, 2A, 3A, 4, and 5A depict one environmental sensor module 270, more than one module 270 may be used. Additionally, the module 270 may be placed in other locations in the sensing device other than the locations shown. For example, in the sensing devices 310 and 510, the sensor module 270 is shown and discussed as being in the second portion 326 respectively. However, the sensor module 270 may be in the first portion 325 of the device 310 or the first portion 525 of the device 510. Additionally, the devices 310 and 510 may include more than one sensor module 270, with some being in the first portion 325 (or the first portion 525 of the sensing device 510) and others being in the second portion 326. In another example, the capacitor 264 of the sensing device 610 (FIG. 6) may be placed outside of the housing 620 while remaining connected to the electrode 662 via the connection 265.

The sensing devices 210, 310, 510, and 610 may have spatial configurations other than those shown. For example, the second connection interface 322 and the second portion 325 of the device 310 has a circular cross-section in the example of FIG. 3A. However, other configurations are possible. For example, the second connection interface 322 and the second portion 326 may have hexagonal cross-sections.

The bushings 190, 490, and 690 may be, for example, cable bushings based on the IEEE 386 standard.

What is claimed is:

1. A sensing device comprising:
a housing comprising an electrical interface and a surface, the surface defining a first connection interface and a second connection interface, the first connection interface configured to connect the housing to a bushing, the second connection interface configured to connect the housing to a separate electrical device, the electrical interface being configured to electrically connect to an electrical conductor of the electrical device;
a capacitive voltage sensor comprising a plurality of capacitors, at least one of the plurality of capacitors being in a first portion of the housing, the at least one capacitor in the first portion of the housing and at least one other capacitor of the plurality of capacitors arranged relative to each other to form a capacitive divider; and
a current sensor in a second portion of the housing, the first portion of the housing and the second portion of the housing being in physical contact with each other.

2. The sensing device of claim 1, wherein
the surface of the housing comprises an inner surface and an outer surface, the inner surface defining an opening,
the opening is the first connection interface and the opening is configured for placement on an exterior of the bushing, and
a portion of the outer surface is the second connection interface and is configured to be received in an opening of the separate electrical device.

3. The sensing device of claim 2, wherein
the plurality of capacitors comprises a first capacitor and a second capacitor,
the first capacitor is the at least one capacitor of the plurality of capacitors in the first portion of the housing, the second capacitor is in the second portion of the housing, and
the first capacitor and the second capacitor are arranged relative to each other to form the capacitive divider.

4. The sensing device of claim 3, wherein the first capacitor comprises:
a first electrode;
a second electrode separated from the first electrode, the second electrode configured for galvanic connection to the electrical conductor; and
a dielectric material between the first and second electrodes.

5. The sensing device of claim 4, wherein the first electrode and the second electrode are in parallel planes and angled relative to a longitudinal axis of the housing.

6. The sensing device of claim 2, wherein the opening defined by the inner surface of the housing is configured to make contact with and surround a portion of the exterior of the bushing.

7. The sensing device of claim 1, wherein the current sensor comprises a Rogowski coil.

8. The sensing device of claim 1, further comprising an electronic module in the second portion of the housing, the electronic module comprising an electronic memory and a data interface, the data interface being accessible from an exterior of the housing.

9. The sensing device of claim 1, wherein the first portion of the housing and the second portion of the housing are a single, integral piece.

10. The sensing device of claim 1, wherein the first portion of the housing and the second portion of the housing are formed as separate pieces configured for physical connection to each other, the first portion of the housing being a first separate piece and the second portion of the housing being a second separate piece.

11. The sensing device of claim 10, wherein the second separate piece is configured to surround at least part of the first separate piece.

12. The sensing device of claim 10, wherein the second capacitor, the electronics module, and the current sensor are encapsulated and spatially fixed relative to each other in the second portion.

13. The sensing device of claim 1, wherein
the plurality of capacitors the plurality of capacitors comprises a first capacitor and a second capacitor,
the first capacitor is in the first portion of the housing, the first capacitor comprising: a first electrode, a second electrode separated from the first electrode, and a dielectric material between the first and second electrodes.

14. The sensing device of claim 13, wherein the second capacitor is formed between one of the first and second electrodes of the first capacitor and an electrical conductor connected to the bushing.

15. A system comprising:
a bushing;
an electrical connector comprising an electrical conductor, the electrical conductor configured for electrical connection to the bushing; and
a sensing device comprising:
a housing configured to be connected between the bushing and the electrical connector;
an electrical interface configured to electrically connect to the electrical conductor;
a capacitive voltage sensor comprising a plurality of capacitors arranged relative to each other to form a capacitive divider configured to measure a voltage, at least one of the plurality of capacitors being in a first portion of the housing; and
a current sensor in a second portion of the housing, wherein,
when the sensing device is connected between the bushing and the electrical connector, the capacitive voltage sensor measures a voltage of the electrical conductor and the current sensor measures a current that flows in the electrical conductor.

16. The system of claim 15, wherein the current sensor comprises a Rogowski coil.

17. The system of claim 15, wherein the housing of the sensing device is a single, integral piece.

18. The system of claim 15, wherein
the first portion of the housing and the second portion of the housing are formed as separate pieces configured to be physically connected to each other,
the first portion of the housing is a first separate piece and the second portion of the housing is a second separate piece, and,
when the sensing device is connected between the bushing and the electrical connector, the first separate piece makes physical contact with the bushing and the electrical connector and the second separate piece surrounds the first separate piece.

19. A method of monitoring an electrical system, the method comprising:
connecting a housing of a sensing device to a bushing and an electrical connector, the housing of the sensing device being between the bushing and the electrical connector, and an electrical conductor of the electrical connector being electrically coupled to the bushing;
receiving an indication of an amount of current flowing in the electrical conductor from a current sensor in the housing; and
receiving an indication of an amount of voltage at the electrical conductor from a capacitive voltage sensor in the housing.
